(19) United States
(12) Patent Application Publication
(10) Pub. No.: US 2008/0105946 A1
(43) Pub. Date: May 8, 2008

(54) SOLID STATE FIELD EMISSION CHARGE STORAGE

(75) Inventor: Bohumil Lojek, Colorado Springs, CO (US)

Correspondence Address: SCHWEGMAN, LUNDBERG & WOESSNER / ATMEL, P.O. BOX 2938, MINNEAPOLIS, MN, 55402, US

(73) Assignee: ATMEL CORPORATION, San Jose, CA (US)

(21) Appl. No.: 11/552,266

(22) Filed: Oct. 24, 2006

(51) Int. Cl. H01L 29/00

(52) U.S. Cl. 257/505

(57) ABSTRACT

Solid state field emission charge storage device is formed by a midgap metal plate and another conductive plate acting as capacitor plates in tunneling relation to a floating charge storage reservoir on a substrate. The plates can be reversibly biased for tunneling of holes or electrons. The devices are tiny islands formed using semiconductor chip fabrication techniques. The islands can form a memory array just as similar islands form a field emitter array for a display screen.

### TECHNICAL FIELD

The invention relates to solid state memories, and in particular, to field emission charge storage devices.

### BACKGROUND ART

Solid state field emitters are used for stimulating phosphors for displays. For example, in U.S. Pat. No. 6,729,928 a polysilicone cone having a metal silicide coating serves as a cathode. An anode that is phosphoric is built opposite the cathode to draw electrons from the cathode with an intermediate gate therebetween. Multiple anodes include multiple phosphors. Individual cones are built in an array of rows and columns and are accessed by a microprocessor addressing row and column decoders.

Field emitters work well for displays because they are fast, responding immediately to changes in electric fields. The switching speed of field emitters is faster than the program or erase speed of most semiconductor non-volatile memory transistors which are more complex structures having greater RC delay. Yet field emitters are not used as solid state charge storage in nonvolatile devices because field emission works well in only a single direction, allowing charge transfer, possibly for storage, but not charge removal, i.e. writing but not erasing, due to an asymmetry in barrier voltages.

An object of the invention was to devise a fast charge storage device, similar to a semiconductor non-volatile memory transistor but with faster program and erase capability.

### SUMMARY OF INVENTION

The above object has been achieved with a new solid state field emission charge storage device having bidirectional program and erase capability achieved with a capacitive structure having thin midgap metal films called “electrodes”, in tunneling relation to an insulated floating conductive charge storage reservoir. Thus, the device has characteristics of both a capacitor and a floating gate transistor, except without source and drain electrodes and without a channel. One of the electrodes, called an “emitter”, is connected to an emitter supply, while the other electrode, called a “collector”, is connected to a plate supply. The words “emitter” and “collector” are words specifically defining electrodes of the solid state device herein and not the electrodes of a BJT device. The electrodes are spaced closely enough for electron tunneling to occur between electrodes when the emitter supply is negative relative to the plate supply.

Some of the electrons emitted from the emitter will overcome the oxide barrier beyond the collector plate and be trapped on the storage reservoir. When polarities on the supplies are reversed, holes migrate from emitter to collector and some are injected into the reservoir where they neutralize electrons.

### BRIEF DESCRIPTION OF THE DRAWINGS

FIGS. 1-4 are side sectional views of manufacturing steps for making a device of the present invention.

FIG. 5 is an alternate embodiment of the device shown in FIG. 4.

### DESCRIPTION OF PREFERRED EMBODIMENT

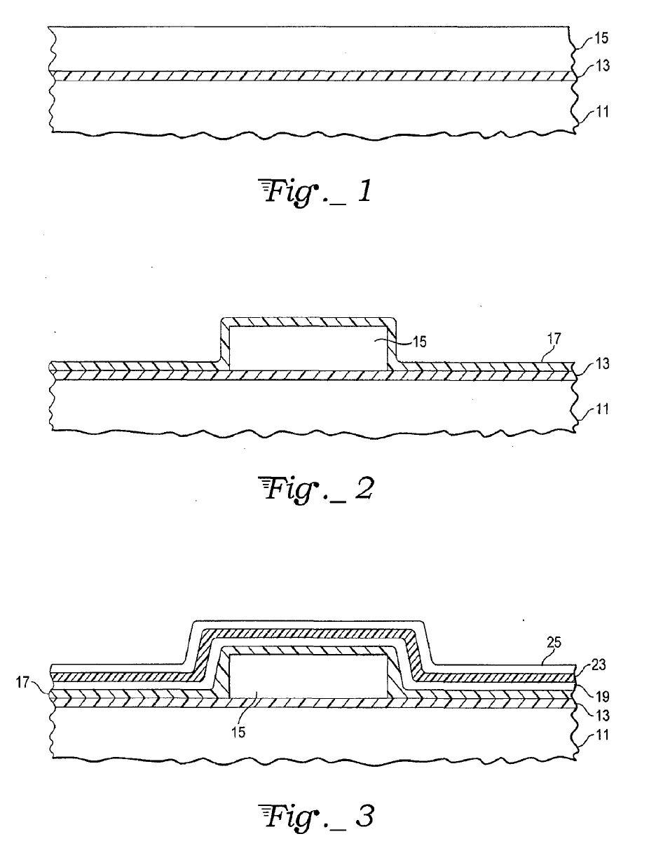

The basic principle employed herein is that the electric field between emitter and collector electrodes of a capacitor-like thin film structure is made sufficiently high that carriers are drawn from the emitter and gain enough energy from the electric field to tunnel through the collector and into an electrically insulated charge storage reservoir below the collector. With reference to FIG. 1, a flat substrate 11 is shown for use as a base to support field emitter charge storage devices of the present invention. Substrate 11 may be a silicon wafer or a glass disk. Silicon is an exemplary material because of its well-known chemical mechanical and electrical properties, its flatness, its availability and because mass production handling tools and facilities presently exist. Although the present invention is illustrated as a single charge storage unit, it is contemplated that arrays of similar devices would be built, similar to memory arrays.

An insulative oxide layer 13 is deposited over substrate 11. The oxide layer would typically have a thickness of approximately 100 Angstroms or less. Some silicon wafers can be obtained commercially with an insulative oxide layer prefabricated. Over the oxide layer 13 a polysilicon layer 15 is deposited by chemical vapor deposition. This layer would have a thickness in the range of 500-1000 Angstroms.

With reference to FIG. 2, the polysilicon layer 15 is patterned to form an island which will ultimately become a charge storage reservoir, similar to a polysilicon floating gate in an EEPROM transistor. An oxide or nitride layer 17 is deposited over the patterned polysilicon charge storage reservoir 15. Whether oxide or nitride is selected depends on subsequent processing to form a thin midgap metal film over layer 17. An oxide layer would have a preferred thickness in the range of 10-50 Angstroms, an electron or hole tunnel distance.

With reference to FIG. 3, other layers are subsequently deposited over the insulative oxide or nitride layer 17. A midgap metal layer 19 is vapor deposited over oxide or nitride layer 17 to a thickness of several nanometers. This metal layer has the thickness and consistency of metal layers that can be made in semiconductor chip manufacturing. Deposition of midgap films is described, for example, in the article “Fabrication of Midgap Metal Gates Compatible with Ultrathin Dielectrics” in Applied Physics Letters, Vol. 73, No. 12, p. 1676-1678 (21 Sep. 1998), by D. A. Buchanan et al. The article describes formation of tungsten film capacitors. Similar film plates are used in the present invention. The term “midgap” as used in this application has the same meaning as used in this article, namely that the Fermi level of the collector material lies in the midband between the valence and conduction band edges of the charge storage material, i.e. silicon n the preferred embodiment. A second oxide or nitride layer 23 similar to the insulative layer 17 is deposited over the metal layer. A conductive layer 25, metal or polysilicon, is deposited over the second oxide or nitride layer 23. The thickness and consistency of the conductive layer 25 is the same as the metal layer 19. The entire structure is then covered with a suitable mask layer and etched to form the field emitter island structure illustrated in FIG. 4.

With reference to FIG. 4, the insulative oxide layer 13, as well as the first oxide or nitride layer 17, the midgap metal layer 19, the second oxide or nitride layer 23, and the conductive layer 25 are all trimmed down to the surface 35 of substrate 11, leaving a mesa or island structure. A first electrical connection 37, a plate voltage, Vₚ, is associated with the midgap metal layer 19. A second emitter voltage on terminal 39 is associated with the conductive layer 25. The two voltages on the two metal layers resemble a capacitor with insulative material in layer 23 between the two metal plates.

When the emitter voltage Vₑ is negative with respect to the collector voltage Vₚ, electrons tunnel from the emitter plate of the conductive layer 25 to the midgap metal layer 19. When the emitter voltage is approximately −4 volts, electrons will reach the first insulative oxide or nitride layer 17 and some of them will overcome the insulative barrier and move to charge storage reservoir 15 where they are trapped.

The charge storage reservoir 15 is seen to have a capacitive relationship with substrate 11, indicated by the virtual capacitor 33. The substrate 11 is grounded, as indicated by grounding connection 31. When the terminal 39 applying emitter voltage is positive with respect to terminal 37 having collector voltage, emitted holes overcome the second oxide or nitride insulative layer 23 as well as the first oxide or nitride layer 17 and are injected into the charge storage reservoir 15. With a collector voltage of approximately 5 volts, the magnitude between the charge storage reservoir 15 and the midgap metal layer 19 required to collect holes injected over the potential barrier is approximately 0.6 volts. The tunneling of electrons and holes may be referred to as “bidirectional”. Therefore the total voltage is approximately 5.6 volts, or roughly 6 volts to inject holes into the reservoir, i.e. removing electrons.

In EEPROMs, injection is usually from the substrate, rather than from above as in the present charge storage device. When injecting from the substrate, there is greater inter-electrode capacitance that slows the device in comparison to a field emitter structure of the type described herein. Greater field emission and charge storage efficiency can be achieved by shaping the charge storage reservoir in a manner that increases electric field strength between the charge storage reservoir and overlying electrodes.

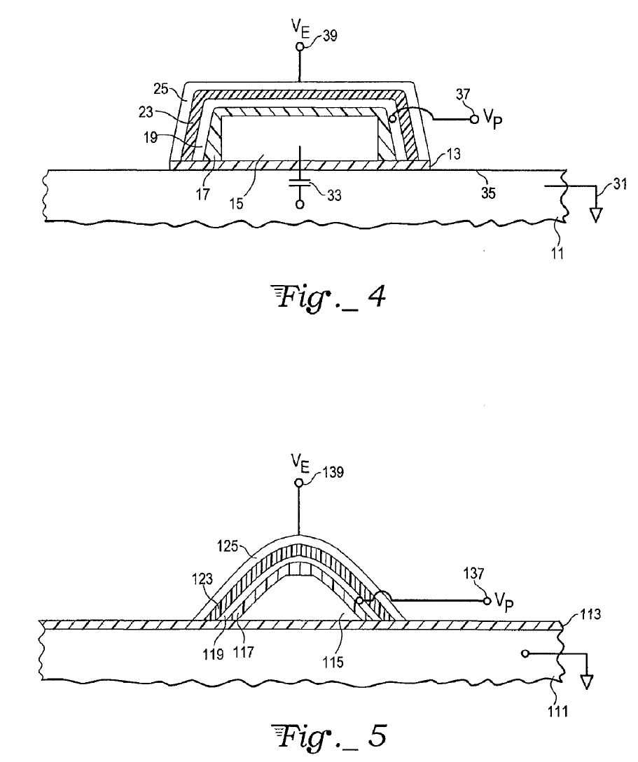

With reference to FIG. 5, charge storage reservoir 115 is seen to be in insulative relationship to substrate 111 by means of the insulative oxide layer 113 and the surrounding insulative layer 117. The polysilicon charge storage reservoir 115 is shaped to have a frustro-conical shape. Such shapes have been built for optical devices, as described in U.S. Pat. No. 6,729,928 mentioned above. Over the first insulative layer 117 is a midgap metal film layer 119 and a second conductive layer 125 separated by the insulative layer 123. Electrical connections are the same as previously described, with the upper or conductive layer 125 connected to terminal 139 and the midgap metal plate connected to terminal 137. Connection to the midgap metal plate 119 may be by means of a via extending through the layers, but not shorting them together. Reversible bias leads to bidirectional tunneling for charge storage and erasing.

The deposition of midgap tungsten films as described by Buchanan et al., supra involves cold wall reactor cracking of W(CO)₆ onto a substrate held in a heated graphite pedestal with a chamber pressure of 5×10⁻⁴ Torr flow conditions and 10⁻⁹ Torr base conditions. The films had a thickness of 2.8 to 7.5 nm, about 20-80 Å, and areas in the range of 1.3×10⁻³ to 5.2×10⁻³ cm². A reactor internal temperature of 450-600° C. was found to be effective. Addressing and final metallization is the same as field emitters for video displays. Spacing of field emitters is at least the same as for video displays but closer spacing is desired as limited by metal wiring.

1. A solid state field emission charge storage device comprising:
a substrate,
an electrically floating, conductive charge storage reservoir on the substrate,
a first insulative layer over the storage reservoir that is sufficiently thin as to permit electron and hole tunneling,
a midgap metal collector electrode over the first insulative layer,
a second insulative layer over the collector plate that is sufficiently thin as to permit electron and hole tunneling, and
a conductive emitter electrode over the second insulative layer.

2. The device of claim 1 wherein the charge storage reservoir is silicon.

3. The device of claim 1 wherein the midgap collector electrode is tungsten.

4. The device of claim 1 wherein the emitter electrode is metal.

5. The device of claim 1 wherein the emitter electrode is polysilicon.

6. The device of claim 1 wherein the substrate is a semiconductor wafer.

7. The device of claim 1 wherein the substrate is glass.

8. A solid state field emission charge storage device comprising:
a midgap metal collector electrode separated by an insulative material from a conductive emitter electrode and in field emission relation therewith,
a conductive, floating, charge storage reservoir separated from the midgap metal collector electrode by an insulative material by a charged particle tunnel distance,
reversible bias means connected to the electrodes for stimulating field emission from the emitter electrode with charged particle tunneling from the collector electrode and into the charge storage reservoir in a bidirectional manner when bias is reversed.

9. The device of claim 8 wherein the emitter electrode plate is polysilicon.

10. The device of claim 8 wherein the midgap collector electrode is tungsten.

11. The device of claim 8 wherein the collector electrode is a midgap metal film.

12. A method of making a field emission charge storage device comprising:
depositing a polysilicon layer on a substrate,
etching the polysilicon layer to form at least one charge storage region,
depositing a first insulative layer over the field emitter region,
depositing a midgap metal layer over the first insulative layer, thereby forming a collector electrode,
depositing a second insulative layer over the first midgap metal layer,
depositing a conductive layer over the second insulative layer as an emitter electrode, the collector electrode in field emission relation to the emitter electrode and the collector electrode in tunnelling relation to the charge storage region.

13. The method of claim 12 wherein the first and second insulative layers are deposited to a thickness in the range of 10-50 Angstroms.

14. The method of claim 12 wherein the midgap metal layer has a thickness in the range of 20-80 Angstroms.

15. The method of claim 12 further defined by shaped etching of the polysilicon layer in a truncated conical shape.
